(19) United States
(12) Patent Application Publication
(10) Pub. No.: US 2026/0029723 A1
(43) Pub. Date: Jan. 29, 2026

(54) ILLUMINATION LIGHT GUIDE, ILLUMINATION OPTICS UNIT AND INSPECTION APPARATUS

(71) Applicant: Carl Zeiss SMT GmbH, Oberkochen (DE)

(72) Inventor: Michael Lohmeier, Schwäbisch-Gmünd (DE)

(21) Appl. No.: 19/268,226

(22) Filed: Jul. 14, 2025

(30) Foreign Application Priority Data
Jul. 26, 2024 (DE) 102024207073.4

(51) Int. Cl. G03F 7/00; F21V 8/00

(52) U.S. Cl. CPC G03F 7/70166; G02B 6/0096; G03F 7/70075; G03F 7/70933; G03F 7/7065

(57) ABSTRACT

An illumination light guide for guiding EUV or DUV illumination light in an illumination optics unit, comprising a tubular guide main body, a guide input and a guide output, wherein the guide main body forms an interior for guiding the illumination light along a longitudinal axis from the guide input to the guide output and wherein a cross-sectional shape of the interior defined perpendicular to the longitudinal axis changes along the longitudinal axis.

### CROSS-REFERENCE TO RELATED APPLICATION

This application claims benefit of the German patent application DE 10 2024 207 073.4, filed on Jul. 26, 2024, which is hereby incorporated by reference in its entirety.

### TECHNICAL FIELD

The present invention relates to an illumination light guide for an illumination optics unit, to an illumination optics unit having such an illumination light guide and to an inspection apparatus having such an illumination optics unit.

### BACKGROUND

On account of prior use, the prior art has disclosed very different types of illumination light guides.

### SUMMARY

A problem that can be addressed by the present invention is that of providing an improved illumination light guide which can be used particularly efficiently in terms of installation space in an illumination optics unit in particular and which does not negatively impact, in particular does not curtail, the beam path of an illumination light beam.

This problem can be solved by an illumination light guide having the features presented in claim 1.

According to the invention, it was recognized that an illumination light guide is configured particularly efficiently in terms of installation space if the cross-sectional shape of the interior changes along the longitudinal direction of the guide main body.

A further advantage lies in the fact that the changing cross-sectional shape allows for an optimal adaptation of the illumination light guide to different conditions and/or requirements in the region of the guide input and of the guide output.

In this context, the cross-sectional shape should be understood to mean the shape of the contour of the cross section, independently of the circumference and/or the surface area of the cross-sectional area of the interior.

In particular, the longitudinal axis may represent an axis of symmetry of the tubular guide main body. In particular, the longitudinal axis may be oriented parallel to the direction of propagation of the illumination light, in particular of a chief ray of the illumination light.

The guide main body forms an interior for guiding the illumination light. In particular, the guide main body encloses the interior at least in part, in particular in the direction perpendicular to the longitudinal axis, for example on the circumferential or lateral side.

In particular, the guide main body may be in the form of a hollow body, for example a tubular guide main body. A cross-sectional shape of the guide main body may vary equivalently to the cross-sectional shape of the interior such that a wall thickness between an inner surface of the interior and an outer surface of the guide main body is constant in the longitudinal direction. As a result, the illumination light guide may be integrated into an illumination optics unit in a manner requiring even less space. Material and manufacturing costs may be reduced.

The cross-sectional shape of the interior of the guide main body may change continuously and/or in discrete steps. The cross-sectional shape preferably changes continuously. An inner face of the guide main body facing the interior is smooth in particular.

In particular, the illumination light guide serves to transfer the illumination light from a first optical component of the illumination optics unit to a second optical component of the illumination optics unit.

The first optical component may be a hollow waveguide in particular. The second optical component may take the form of an output-coupling mirror optics unit. The first and/or the second optical component, and optionally further component parts arranged adjacent to the first and/or second optical components, may significantly curtail the installation space for the illumination light guide. Optimal use of this significantly curtailed installation space may be rendered possible by use of an illumination light guide according to the invention.

At the same time, it was surprisingly discovered that a beam path of the illumination light is not impacted negatively and in particular not curtailed despite the changing cross-sectional shape of the interior. An illumination light guide according to the invention can be integrated efficiently in terms of installation space into the illumination optics unit in particular, without negative effects as regards the illumination light and a deficient illumination optics unit accompanying this being expected.

The guide input and/or the guide output may in particular be arranged in planes orthogonal to the longitudinal direction. In particular, the guide input may be arranged at a first end of the tubular main body. In particular, the guide output may be arranged at an end, which is opposite the first end in relation to the longitudinal direction.

An illumination light guide according to claim 2 may be adapted precisely to the requirements, in particular installation space-related conditions as regards the overarching illumination optics unit, in the region of the guide input and/or of the guide output.

The cross section of the guide input and/or the cross section of the guide output may have a cross-sectional area and/or a cross-sectional shape.

In this case, the cross section of the guide input and the cross section of the guide output may mean the respective cross sections of the interior of the illumination light guide at the guide input and guide output, respectively.

It is also possible that the cross section of the guide input and the cross section of the guide output refer to the respective cross sections of the outer surface of the illumination light guide at the guide input and guide output, respectively.

In this case, a side ratio of a cross section, for example the input side ratio of the guide input or the output side ratio of the guide output, is understood to mean in particular a ratio of a length to a width of the smallest rectangle that forms an envelope for the cross section, i.e. in particular of the smallest rectangle whose area completely contains the cross section.

As a result of the different side ratios, the guide input and/or the guide output may be ideally adaptable to the installation space that is predetermined by the further optical components of the illumination optics unit and/or to a functional and/or mechanical coupling to these components.

An illumination light guide according to claim 3 is particularly well suited to the relevant practical application in which the illumination light has a beam cross section that has different extents in different spatial directions and is elliptical in particular. Light, in particular for mask inspection, may be guided precisely as a result.

An illumination light guide according to claim 4 can be manufactured particularly easily. As a result of an input side ratio of substantially 1, preferably exactly 1, the guide input has a particularly large number of symmetries, in particular rotational symmetries. The guide input may have a rotationally symmetric form in particular. In general, it is easier to manufacture symmetrical structural elements.

Moreover, the symmetry of the guide input allows the efficient integration of further functional components into the illumination light guide, in particular the integration of a purging device for upstream optical components, for example for a hollow waveguide. The symmetry ensures a uniform embodiment and/or effect of the functional components, for example a uniform supply of purge gas.

An illumination light guide according to claim 5 has proven its worth in practice. As a result of the chosen output side ratio, the illumination light guide can be integrated into the overarching illumination optics unit with particular optimization in terms of installation space.

In particular, it is possible that the following applies to the output side ratio S₂: 1.2<S₂<1.8, in particular 1.3<S₂<1.7, in particular 1.4<S₂<1.6 and in particular S₂=1.5.

An illumination light guide according to claim 6 allows even more efficient use of the available installation space. Empirically, the installation space of the illumination optics unit is smaller in the region of the guide output or in the region of the guide input. A conical configuration of the tubular guide main body allows this to be taken into account when constructing the illumination optics unit.

The interior of the guide main body may also take a conical form. The wall thickness between the outer surface of the guide main body and the inner surface of the interior may also be constant in this case.

In particular, it is possible that the cross-sectional area of the guide output is larger than the cross-sectional area of the guide input. In this case, the interior of the guide main body widens along the longitudinal axis in the direction of propagation of the illumination light. As a result, the illumination light, which has an expanding beam cross section, may be reliably guided without being impaired.

An illumination light guide according to claim 7 can be manufactured easily and precisely. Component parts with circular contours can be produced by use of a large variety of production methods. Moreover, the guide input has a particularly high degree of symmetry, improving the arrangement on and/or the functional interaction with upstream components.

A guide output according to claim 8 is particularly suitable for illumination light with an elliptical beam cross section.

An illumination light guide according to claim 9 can be integrated particularly easily into the illumination optics unit. In particular, the guide input has a square cross-sectional shape. The optical component upstream of the illumination light guide, in particular the hollow waveguide, may have a hollow waveguide cross section that is rectangular by way of example and square in particular. The cross-sectional shape of a regular polygon, in particular of a square, allows good coupling and/or functional interaction between the upstream component and the illumination light guide. In the region of the guide input, the illumination light guide has a high degree of symmetry.

Moreover, the hollow waveguide in particular may have a waveguide cavity that has a substantially rectangular, in particular square contour. In this case, the illumination light may be transferred particularly efficiently from the hollow waveguide to the illumination light guide.

An illumination light guide according to claim 10 can be integrated particularly efficiently in terms of installation space into an illumination optics unit. In particular, it is possible for the cross-sectional shape to be rectangular, in particular with a side ratio not equal to 1.

An illumination light guide according to claim 11 can be used particularly flexibly. As a result of integrating further functional components into the illumination light guide, in particular into a guide base of the illumination light guide, other component parts of the illumination optics unit, in particular the optical component disposed directly upstream of the illumination light guide, may be influenced in a targeted manner in order to ensure a frictionless and efficient functionality of the illumination optics unit.

An illumination light guide according to claim 12 allows efficient purging and/or cleaning of the upstream optical component, in particular of the upstream hollow waveguide. The purging device is a waveguide purging device in particular.

The illumination light guide may in particular comprise a purge gas connector in order to supply purge gas, in particular hydrogen gas, from a purge gas reservoir to the upstream optical component in a targeted, more particularly controlled, fashion. The purge gas flow may be controlled particularly effectively as a result. The purge gas connector may be arranged at a distance from the sensitive optical components.

In an alternative to the purge gas connector or in addition, further constituent parts of the purging device may be integrated into the illumination light guide, in particular into the guide base. In particular, pressure chambers, intermediate gaps and/or nozzles may be integrated into the illumination light guide, in particular into the guide base.

It is also possible that constituent parts of the purging device are formed between the illumination light guide, in particular the guide base, and a cover of the upstream optical components, in particular a cover of a hollow waveguide.

A further problem that can be addressed by the invention is that of improving an illumination optics unit.

This problem can be solved by an illumination optics unit having the features presented in claim 13.

The illumination optics unit may be part of an inspection apparatus, for example for inspecting photolithographic masks and/or photolithographic wafers.

An illumination optics unit according to claim 14 may provide and/or focus particularly homogeneous illumination light.

An illumination optics unit according to claim 15 is particularly compact. The constituent parts of the purging device may in particular be fully integrated into the illumination light guide, in particular into the guide base, or be formed between the illumination light guide, in particular the guide base, and a cover of the hollow waveguide.

A further problem that can be addressed by the invention is that of improving an inspection apparatus.

This problem can be solved by an inspection apparatus having the features presented in claim 16.

In particular, the inspection apparatus may be designed to inspect photolithographic masks and/or photolithographic wafers. In particular, the inspection apparatus may take the form of an actinic inspection apparatus, i.e. use light in the extreme ultraviolet (EUV) wavelength range.

It is also possible that the inspection apparatus uses light from a different wavelength range, for example the deep ultraviolet (DUV) wavelength range.

In addition to the illumination optics unit, the inspection apparatus may also comprise a projection optics unit that serves to image light reflected off the mask to be inspected and/or off the wafer to be inspected into an image plane.

### BRIEF DESCRIPTION OF DRAWINGS

An exemplary embodiment of the invention is explained in detail below with reference to the drawing, in which:

FIG. 1 schematically shows an optical system having an illumination optics unit for a mask inspection system for use with EUV illumination light;

FIG. 2 shows a schematic view of a sectional illustration of a first exemplary embodiment of a hollow waveguide assembly having a waveguide purging device and an illumination light guide;

FIG. 3 shows a schematic view of a sectional illustration of a further exemplary embodiment of a hollow waveguide assembly having a waveguide purging device and an illumination light guide;

FIG. 4 shows a schematic view of a sectional illustration of a third exemplary embodiment of a hollow waveguide assembly having a waveguide purging device and an illumination light guide;

FIG. 5 shows a perspective view of an exemplary embodiment of an illumination light guide;

FIG. 6 shows a sectional illustration of the illumination light guide according to FIG. 5; and

FIG. 7 shows a schematic view of a guide input of an illumination light guide according to FIG. 5.

### DETAILED DESCRIPTION

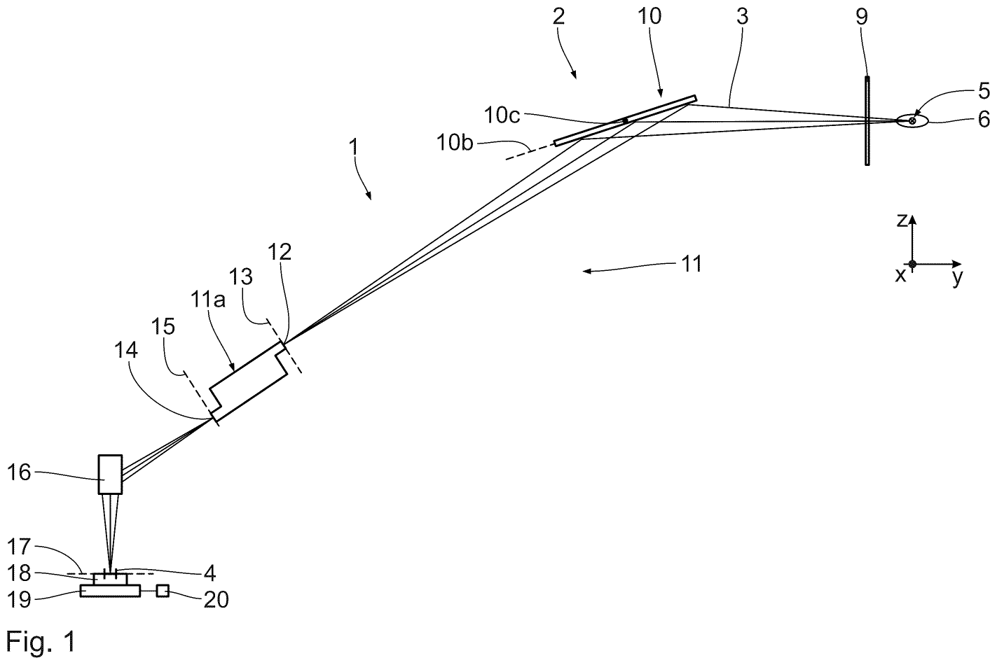

Referring to FIG. 1, an illumination optics unit 1 is a constituent part of an illumination system 2 of a mask inspection system for use with EUV illumination light 3. In the drawing, a beam path of the illumination light 3 is illustrated by way of marginal rays. An illumination field or object field 4 of the mask inspection system is illuminated by the illumination light 3.

The illumination light 3 is created by an EUV light source 5 in a source region or source volume 6. The light source 5 can create EUV used radiation in a wavelength range of between 2 nm and 30 nm, for example in the range of between 2.3 nm and 4.4 nm or in the range of between 5 nm and 30 nm, for example at 13.5 nm.

The light source 5 may be embodied as a plasma light source. For example, it can be a laser plasma source (LPP; laser produced plasma) or else a discharge source (DPP; discharge produced plasma). It is also possible to use a high-harmonic EUV source. In principle, such plasma sources are known light sources for EUV projection exposure apparatuses.

In order to facilitate positional relationships, a Cartesian xyz-coordinate system will be used hereinafter. The x-axis is perpendicular to the drawing plane of FIG. 1. The y-axis runs horizontally to the right in FIG. 1, and the z-axis runs vertically upwards in FIG. 1.

The source region 6 has an approximately ellipsoidal shape and has a greatest extent, which is also referred to as main direction of extent, parallel to the y-axis. A main emission direction of the illumination light 3 from the source region 6 runs along this main direction of extent, i.e. along a longest major axis of the ellipsoidal source region 6 in the case of an ellipsoidal approximation.

Following its emission by the light source 5, the illumination light 3 initially passes through an aperture stop 9 which delimits the edge of a beam of the illumination light 3.

The aperture stop 9 can be designed to be interchangeable. For example, a stop wheel may be provided to this end, the latter storing various aperture stop embodiments which can be used alternately within the beam path of the illumination light 3. Different input apertures of the illumination light 3 may be specified by way of such an interchangeable aperture stop design.

The aperture stop 9 may be embodied to be interchangeable and/or adjustable, and/or settable in respect of its stop edge. Different stop geometries of the aperture stop 9 can be realized and/or set as a result. For example, specifiable stop geometries might be round with a selectable diameter and/or elliptical with a selectable ellipse size and optionally with a selectable semi-axis ratio of the ellipses. Such a semi-axis ratio of an ellipse specifiable by way of the aperture stop 9 may be 2:1.

Downstream of the aperture stop 9, the illumination light beam 3 is transferred from an input coupling mirror 10 to a beam homogenization device 11 of the illumination optics unit 1. As yet to be explained in detail below, the input coupling mirror 10 may also be part of the beam homogenization device 11. A beam-homogenizing element, for example a hollow waveguide 11a in this case, may be part of the beam homogenization device 11. In other exemplary embodiments, the beam homogenization device 11 may in an alternative to that or in addition also comprise at least one facet mirror serving to divide the EUV illumination light 3 into a plurality of individual beams that should be superimposed on one another for the purpose of homogenizing mixing. In this case, the beam homogenization device may also comprise, e.g., two successively arranged facet mirrors.

The aperture stop 9 restricts a numerical aperture of the illumination light beam 3 emitted by the source region 6 to a value of the numerical aperture in the range of between 0.02 and 0.3, for example in the range of between 0.02 and 0.1 or between 0.05 and 0.08. A numerical aperture as specified by the aperture stop 9 of greater than 0.1, i.e. in the range of between 0.1 and 0.3, allows a greater light yield in the illumination light beam path between the source volume 6 and the illumination field 4.

An incoherent illumination setting may be used.

In an alternative to the aperture stop 9 or in addition, an aperture-limiting stop may be arranged between the hollow waveguide 11a and a downstream optical component of the illumination optics unit 1. An arrangement of such a further aperture stop in the beam path of the illumination light 3 downstream of the hollow waveguide 11a between two downstream optical components of the illumination optics unit 1 is also possible.

For example, the input coupling mirror 10 is embodied as an ellipsoid mirror and serves to image the source region 6 of the EUV light source 5 into a waveguide input 12 in an entrance plane 13 of the hollow waveguide 11a. A first focus of the ellipsoid mirror 10 is therefore located in the source region 6 and a second focus of the ellipsoid mirror 10 is located in the waveguide input 12 or in the region of the waveguide input 12. The ellipsoid mirror 10 is used to focus the illumination light beam 3 into the waveguide input 12 in the entrance plane 13 of the hollow waveguide 11a. An entrance-side numerical aperture of the illumination light beam 3 upon entry into the waveguide input 12 may be in the range of between 0.02 and 0.2, for example be of the order of 0.15 or be of the order of 0.05 or 0.1.

In the embodiment of the illumination optics unit 1 according to FIG. 1, the ellipsoid mirror 10 represents a mirror for grazing incidence (GI).

Depending on the embodiment of the input coupling optics unit, the latter has exactly one input coupling mirror, as depicted in FIG. 1 using the example of the input coupling mirror 10, or else a plurality of input coupling mirrors, e.g. two or three input coupling mirrors.

The waveguide input 12 and a waveguide output 14 of the hollow waveguide 11a are square or rectangular in each case, with typical dimensions in the range of between 0.5 mm and 5 mm. An aspect ratio of the waveguide input 12 and of an identically sized waveguide output 14 of the hollow waveguide 11a for the illumination light 3 in an exit plane 15 is between 0.25 and 4, for example between 0.5 and 2. Typical dimensions of the waveguide input 12 and of the waveguide output 14 of the hollow waveguide 11a are 0.75 mm×0.75 mm, 1.0 mm×2.0 mm or 1.5 mm×2.0 mm.

An inner wall of a waveguide cavity of the hollow waveguide 11a is provided with a highly reflective coating for the illumination light 3, for example a ruthenium coating. The waveguide cavity is cuboid, in accordance with the rectangular waveguide input and waveguide output 12, 14. The hollow waveguide 11a has a typical length in the beam direction of the illumination light 3 in the range of between 10 and 500 mm, for example in the range of between 20 mm and 500 mm, between 20 mm and 300 mm, or else between 20 mm and 80 mm.

Angles of incidence of the illumination light 3 on the inner wall of the waveguide cavity of the hollow waveguide 11a are greater than 60°, for example. Illumination light 3 impinges on the inner wall with grazing incidence.

An angle between a longitudinal axis of the hollow waveguide 11a and the chief ray of the illumination light beam 3 incident into the waveguide input 12 may be 0° or may alternatively also differ from 0° and for example be in the range of between 0° and 1.5°, for example between 0.25° and 0.75° and in particular be of the order of 0.5°.

A ratio of the length of the hollow waveguide 11a, i.e. the distance between the entrance plane 13 and the exit plane 15, to a typical diameter of the hollow waveguide 11a, i.e. the typical dimensions or typical diameter of the waveguide input 12 or of the waveguide output 14, is in the range of between 10 and 1000 and may for example be between 10 and 500, between 30 and 500, between 30 and 300, or else between 30 and 80 or between 200 and 500.

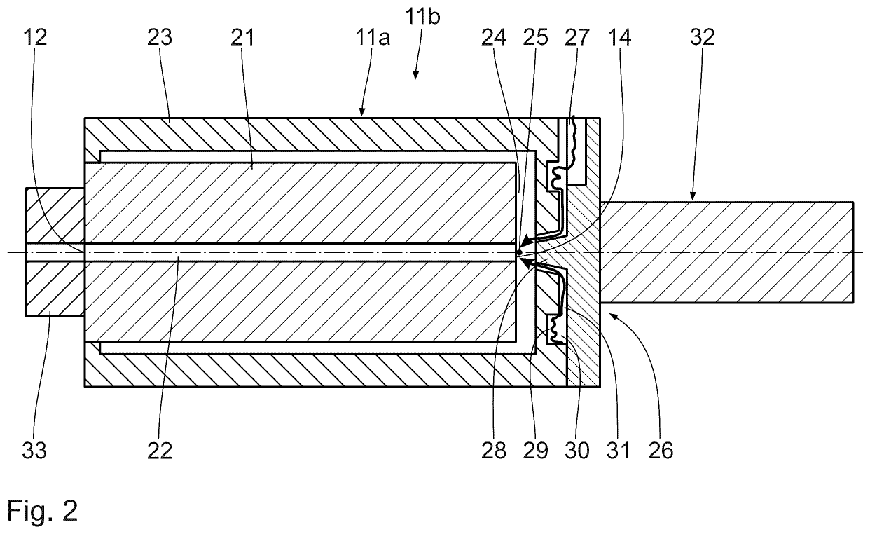

Such a hollow waveguide 11a may be exposed to contamination as a result of material removal and/or external dirtying. A purge gas device (not depicted in FIG. 1) serves to clean the hollow waveguide 11a and is explained in detail below on the basis of exemplary embodiment variants, with reference being made to FIGS. 2 to 4.

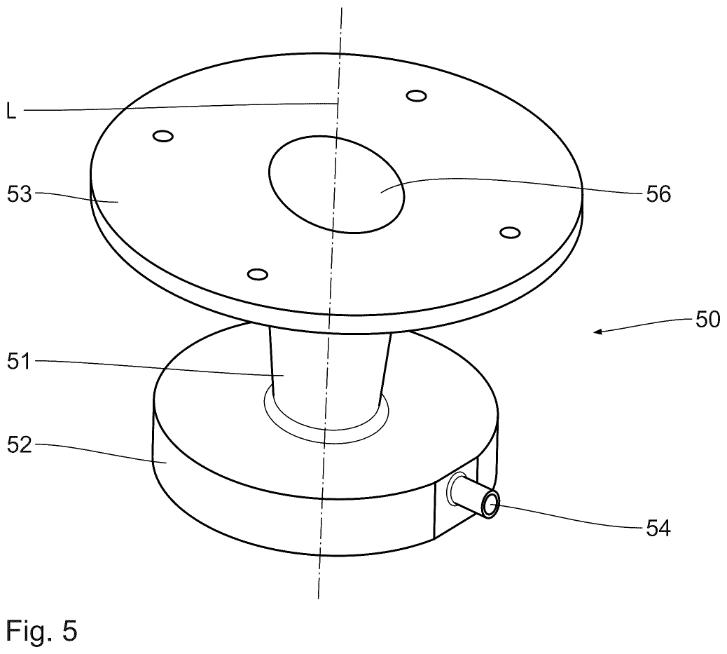

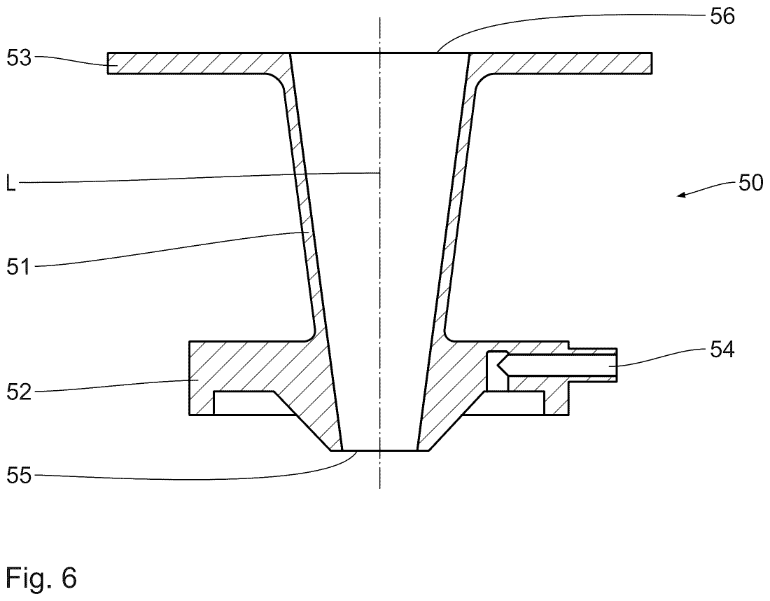

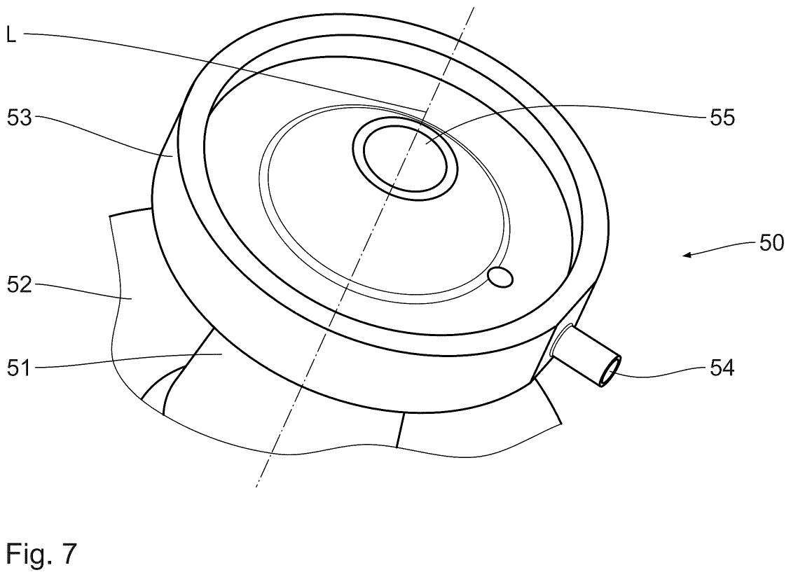

It is possible that the illumination light 3 is transferred to the overarching optical system by use of an illumination light guide (not depicted in FIG. 1). An exemplary illumination light guide is explained in detail below with reference to FIGS. 5 to 7.

An imaging output-coupling mirror optics unit 16 depicted schematically in FIG. 1 and situated downstream of the hollow waveguide 11a images the waveguide output 14, located in an exit plane 15, of the hollow waveguide 11a into the illumination field 4 in an object plane 17. This imaging may have an image-side numerical aperture in the range of between 0.1 and 0.3.

The e.g. two or more mirrors of the output-coupling mirror optics unit 16 may be embodied as mirrors for grazing incidence of the illumination light 3.

The above-described, optionally used aperture stop downstream of the hollow waveguide 11a may be arranged between the hollow waveguide 11a and a first mirror of the output-coupling mirror optics unit 16 or else between different mirrors of the output-coupling mirror optics unit 16.

The output-coupling mirror optics unit 16 may be embodied in the style of a Wolter telescope, specifically in the style of a Type I Wolter optics unit. Such Wolter optics units are described in J. D. Mangus, J. H. Underwood “Optical Design of a Glancing Incidence X-ray Telescope,” Applied Optics, Vol. 8, 1969, page 95, and the references cited therein. In such Wolter optics units, a hyperboloid may also be used in place of a paraboloid. Such a combination of an ellipsoid mirror with a hyperboloid mirror also constitutes a Type I Wolter optics unit.

A further exemplary embodiment of the output-coupling mirror optics unit 16 is described in U.S. Pat. No. 10,042,248 B2. Alternatively, mirrors of the output-coupling mirror optics unit 16 may also comprise reflection surfaces in the form of free-form surfaces.

A reticle 18 to be inspected, which is held by a reticle holder 19, is arranged in the object plane 17. The reticle holder 19 is mechanically operatively connected to a reticle displacement drive 20, by means of which the reticle 18 is displaced in an object displacement direction y during a mask inspection. In this way, a scanning displacement of the reticle 18 in the object plane 17 is possible.

The illumination field 4 has a typical dimension in the object plane 17 that is less than 1 mm and may be less than 0.5 mm. In the embodiment illustrated, the extent of the illumination field 4 is 0.5 mm in the x-direction and 0.5 mm in the y-direction.

The x/y aspect ratio of the illumination field 4 may correspond to the x/y aspect ratio of the waveguide output 14.

Using a projection optics unit not depicted in FIG. 1, the illumination field 4 is imaged into an image field in an image plane.

The image field is detected by a detection device, for example one charge coupled device (CCD) camera or a plurality of CCD cameras. Regarding details of the imaging into the image field, reference is made to U.S. Pat. No. 10,042,248 B2 and the references specified herein and in U.S. Pat. No. 10,042,248 B2. The entire content of U.S. Pat. No. 10,042,248 B2 is herein incorporated by reference.

An inspection of a structure on the reticle 18, for example, is possible by use of the mask inspection system.

An imaging factor β₁ of the input-coupling mirror optics unit 10 may be in the range of between 0.1 and 50, i.e. its action may vary from a reduction by a factor of 10 to a magnification of a factor of 50. An imaging factor β₂ of the output-coupling mirror optics unit 16 may be in the range of between 0.02 and 10, i.e. its action in turn may vary from a reduction by a factor of 50 to a magnification of a factor. In the case of the illumination optics unit 1, a product β₁, β₂ of the two imaging factors may range between 0.25 and 10.

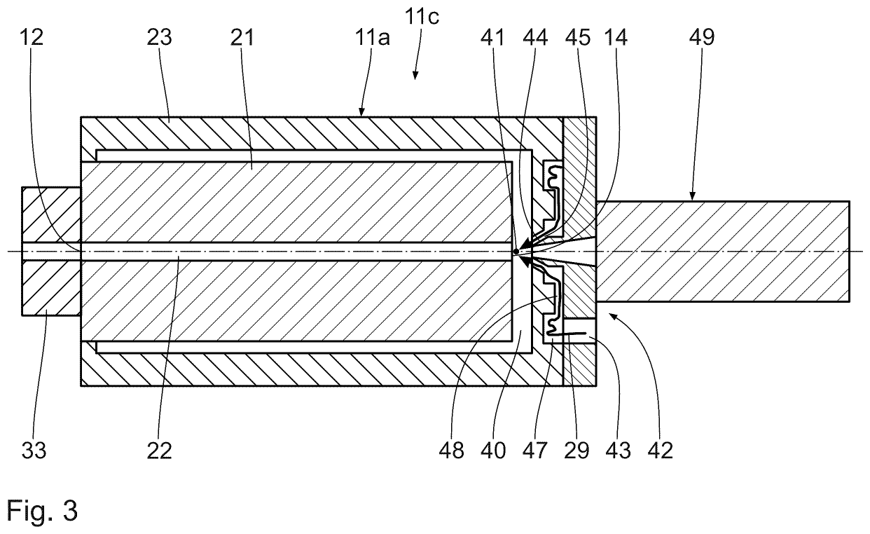

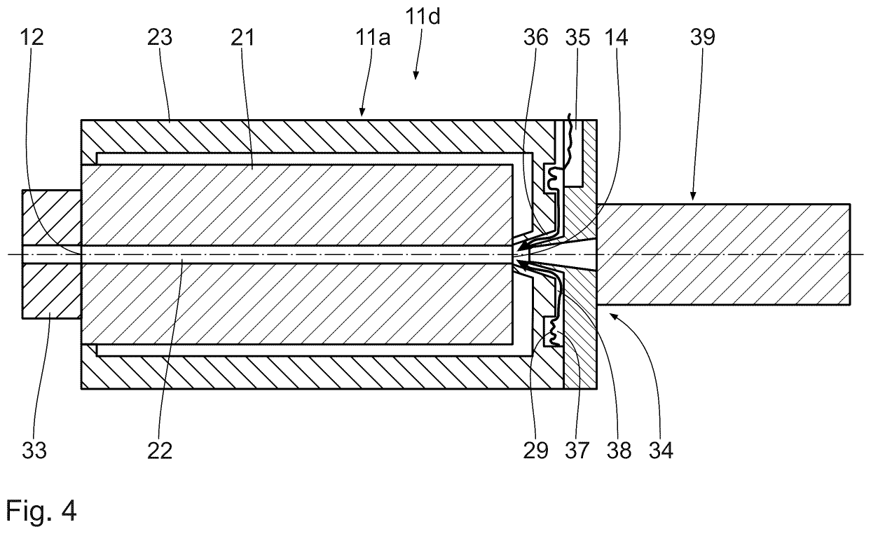

Three exemplary embodiments of an optical hollow waveguide assembly 11b with a hollow waveguide 11a comprising a purge gas device and an illumination light guide are explained in detail below with reference to FIGS. 2 to 4. Initially, an exemplary embodiment is explained in detail on the basis of FIG. 2. Identical components in the exemplary embodiments according to FIGS. 3 and 4, which are explained subsequently, bear identical reference signs and are not described in detail again.

The hollow waveguide 11a has a main body 21. In particular, the main body 21 may be formed from multiple parts. As regards a possible embodiment of the main body 21 of the hollow waveguide 11a, reference is made to DE 10 2014 219 112 A1, in particular FIG. 3 and the associated description therein, the disclosure of which is fully incorporated into this application by reference.

A waveguide cavity 22 is formed in the interior of the main body 21. In particular, the waveguide cavity 22 has an inner face that is coated with a coating, for example made of ruthenium, that is highly reflective for light in the EUV or DUV range.

The main body 21 is surrounded by a cover 23. The cover 23 primarily serves to protect the main body 21.

The hollow waveguide assembly 11b moreover comprises a waveguide purging device 26 having a purge gas connector 27 and a nozzle 28. The waveguide purging device 26 serves to purge the hollow waveguide 11a, in particular the waveguide cavity 22, with purge gas 29. In particular, the hollow waveguide 11a may be purged continuously with purge gas 29. In particular, hydrogen gas may be used as purge gas 29. The purge gas connector 27 may be connected to a purge gas source, such as a hydrogen gas source, or a purge gas storage, such as a hydrogen gas storage, which produces and/or stores the purge gas. For example, the purge gas connector 27 may be connected to the purge gas source and/or purge gas storage via a purge gas supply line. The purge gas supply line may comprise mechanisms to actively or passively control the flow of purge gas 29 to the purge gas connector 27.

In the exemplary embodiment according to FIG. 2, the cover 23 is attached to the main body 21 in such a way that an accumulation chamber 24 is formed in the region of the waveguide output 14. An accumulation point 25 forms within the accumulation chamber 24 and substantially coincides with the waveguide output 14.

For example, the accumulation chamber 24 may be a free space formed between the end face of the waveguide main body 21 and further components, in particular the cover 23, in the region of the waveguide output 14. For example, the cover 23 may be spaced apart from the main body 21 along the central longitudinal axis of the hollow waveguide 11a to form the accumulation chamber 24. In a direction perpendicular to the central longitudinal axis of the hollow waveguide 11a, the shape of the accumulation chamber 24 may essentially correspond to the cross section of the main body 21 perpendicular to the central longitudinal axis of the hollow waveguide 11a.

The purge gas 29 is initially introduced into a pressure chamber 30 of the waveguide purging device 26 via the purge gas connector 27. The pressure chamber 30 serves to reduce a first pressure P₁ and a first speed V₁, at which the purge gas flows in via the purge gas connector 27. The pressure chamber 30 may be formed in particular in a ring-shaped fashion around a beam path of the illumination light/central longitudinal axis of the hollow waveguide 11a. This enables the purge gas to be uniformly distributed and adapted in terms of pressure and/or speed even with one-way supply via the purge gas connector 27. The pressure chamber 30 may be disposed directly or indirectly downstream of the purge gas connector 27. In the latter case, the purge gas connector 27 may be fluidically connected to the pressure chamber 30 by use of an additional purge gas line, for example. In some examples, the one or more pressure chambers 30 are parts of or act as a reducer for reducing a pressure and/or a speed of the supplied purge gas. For example, the reducer may be established by the pressure chamber 30. In other examples. The reducer may comprise the pressure chamber 30 and downstream purge gas lines, such as an intermediate gap formed between the pressure chamber 30 and the nozzle 28.

In particular, the pressure P₁ may be in the range of 30 Pa to 50 Pa. In particular, the speed V₁ may be in the range of 800 m/s to 900 m/s. An intermediate gap 31, through which the purge gas 29 flows out of the pressure chamber 30 and into the nozzle 28 and is introduced into the accumulation chamber 24 as a result, is arranged between the pressure chamber 30 and the nozzle 28. For example, the intermediate gap 31 can be defined by in particular a cross-sectional area that is smaller than a cross-sectional area of the pressure chamber 30. A cross-sectional narrowing may be formed upon transition from the pressure chamber 30 to the intermediate gap 31. A cross-sectional widening may be formed upon transition from the intermediate gap 31 to the nozzle 28. The intermediate gap 31 may be ring-shaped like the pressure chamber 30. The pressure chamber 30 and/or the intermediate gap 31 may be formed between different components, such as between the cover 31 and a downstream illumination light guide 32. As a result of the eddies arising when the purge gas 29 is introduced, it is possible to deliberately set a second pressure P₂ and a second speed V₂ at the accumulation point 25. In particular, the second pressure P₂ is in the range of 15 Pa to 25 Pa. In particular, the second speed V₂ is in the range of 20 m/s to 30 m/s.

As a result of the pressure P₂ arising at the accumulation point 25, the purge gas 29 flows into the waveguide cavity 22 and leaves the waveguide cavity 22 at the waveguide input 12. When passing through the waveguide cavity 22, the purge gas 29 will experience a loss of pressure ΔP as a result of friction, inertia of the purge gas 29 and an interaction of the purge gas 29 with the illumination light 3. The purge gas 29 has a third speed V₃ and a third pressure P₃ in the waveguide cavity 22. In particular, the third speed V₃ may be in the range of 5 m/s to 10 m/s. In particular, the third pressure P₃ may be in the range of 10 Pa to 15 Pa.

In particular, it is possible that the waveguide input 12 and the waveguide output 14 are located at different heights in the Earth's gravitational field, which may influence, in particular increase, the loss of pressure ΔP₃. In particular, the loss of pressure ΔP₃ may be in the range of 10 Pa to 15 Pa.

A fourth pressure P₄ and/or a fourth speed V₄ sets in at the waveguide input 12. In particular, the fourth pressure P₄ may be less than 10 Pa. In particular, the fourth speed V₄ is in the range of 4 m/s to 6 m/s.

As a result, it is possible to purge, in particular continuously purge, the hollow waveguide 11a against the flow. In this context, “against the flow” means that a direction of propagation of the purge gas 29 runs antiparallel to a direction of propagation of the illumination light 3.

Sensors 33 are attached to the waveguide input 12. In particular, the sensors 33 are able to detect the pressure P₄ and/or the speed V₄. The sensors 33 may also measure properties of the illumination light 3, for example its intensity and/or energy. It is also possible that the sensors 33 take the form of purge gas sensors 33 in order to detect a flow rate of the purge gas 29. In particular, the waveguide purging device 26 allows the waveguide 11a, in particular its waveguide cavity 22, to be purged without impairing the positioning and/or function of the sensors 33 at the waveguide input 12.

An illumination light guide 32 that serves to transfer the illumination light 3 from the hollow waveguide to the output-coupling mirror optics unit 16 is arranged at the waveguide output 14. An exemplary illumination light guide 32 is explained in detail below with reference to FIGS. 5 to 7.

The nozzle 28 is used to introduce the purge gas 29 into the waveguide output 14 indirectly, via the accumulation chamber 24. In the exemplary embodiment shown, at least parts of the waveguide purging device 26, in particular the pressure chamber 30, the intermediate gap 31 and the nozzle 28, are formed between the cover and a base of the illumination light guide 32 that faces the hollow waveguide 11a and a side of the cover 23 that faces the illumination light guide 32. For example, appropriate structures that form the corresponding parts of the waveguide purging device 26 when the illumination light guide 32 is secured to the cover 23 may be introduced into the cover 23 and the base of the illumination light guide 32.

For example, the nozzle 28 may be formed between the cover 23 and the illumination light guide 32. As a result, the nozzle 28 may be formed as an annular nozzle, for example. It is also possible to form a plurality of nozzles or nozzle openings between the cover 23 and the illumination light guide 32.

In other exemplary embodiments, at least parts of the waveguide purging device 26, in particular a purge gas connector, a pressure chamber, an intermediate gap and/or one or more nozzles, may be fully integrated into the illumination light guide 32, in particular into the base thereof.

As a result of introducing the purge gas 29 into the accumulation chamber 24, turbulence and/or eddies in the purge gas may be deliberately induced in the accumulation chamber. This turbulence and/or these eddies are particularly pronounced at the accumulation point 25. This may increase the dynamic pressure at the accumulation point 25, whereby a purge gas flow through the waveguide cavity 22 may be improved.

FIG. 3 illustrates a further exemplary embodiment of an optical hollow waveguide assembly 11c, in which the purge gas 29 is introduced indirectly into the waveguide cavity 22 by use of an accumulation chamber 40 and an accumulation point 41. A waveguide purging device 42 having a purge gas connector 43 and a nozzle 44, which has a multiplicity of nozzle openings 45, is also depicted. The waveguide purging device 42 comprises a pressure chamber 47 and an intermediate gap 48.

By using more than one nozzle opening 45, it is possible to influence the eddies in the accumulation chamber 40 particularly deliberately. As a result, the second pressure P₂ and/or the second speed V₂ at the accumulation point 41 can be set particularly precisely.

The nozzle 44 may comprise two nozzle openings 45 in particular, at least three nozzle openings 45 in particular and at least four nozzle openings 45 in particular. In particular, the nozzle openings 45 may be arranged symmetrically around the accumulation point 41.

The waveguide purging device 42 is designed as part of the cover 23 or at least partially integrated into the cover 23.

The optical hollow waveguide assembly 11c comprises an illumination light guide 49, which is formed as a separate component part from the waveguide purging device 42. In particular, the illumination light guide 49 may be connected to the waveguide purging device 42 and in particular fastened to the waveguide purging device 42. It is also possible to integrate individual components of the waveguide purging device 42 into the illumination light guide 49 and/or form these between the cover 23 and the illumination light guide 49.

What is depicted in accordance with the exemplary embodiment according to FIG. 4 is an optical hollow waveguide assembly 11d with a waveguide purging device 34 with a purge gas connector 35 and a nozzle 36. In accordance with the exemplary embodiment according to FIG. 4, too, the waveguide purging device 34 comprises a pressure chamber 37 and an intermediate gap 38.

The exemplary embodiment according to FIG. 4 predominantly differs from the above-described exemplary embodiments in that the purge gas 29 is introduced directly into the waveguide cavity 22. It is possible to leave out an accumulation chamber 24 and an associated accumulation point 25. The nozzle 36 is arranged on the circumferential side of a cross section of the waveguide output 14 in such a way that purge gas 29 flows directly onto the waveguide output 14.

FIG. 4 moreover likewise depicts an illumination light guide 39 which is designed as a separate component part from the waveguide purging device 34.

FIGS. 5 to 7 show an exemplary embodiment of an illumination light guide 50. For example, the illumination light guide 50 may be used in the above-described exemplary embodiments, especially in the exemplary embodiment according to FIG. 2.

In this case, the illumination light guide 50 comprises a guide main body 51, a guide base 52 and a guide cover plate 53.

The guide base 52 serves for a connection, in particular a fluid-tight connection, to the hollow waveguide 11a, in particular to the cover 23 thereof. The guide cover plate 53 serves to connect, in particular flange, the illumination light guide 50 to downstream components in the beam path of the illumination light 3.

An above-described waveguide purging device may be integrated, at least in part, into the guide base 52. In the exemplary embodiment shown, the guide base 52 is designed such that fluid channels for forming the purging device are introduced on the side that faces away from the main body 51. Following the fluid-tight connection of the guide base 52 to a cover 23 of the hollow waveguide 11a, fluid channels, for example the pressure chamber 30, are formed between the guide base 52 and the cover 23. The purge gas connector 54 is integrated into the guide base 52.

In other exemplary embodiments (not depicted in the figures), the waveguide purging device is fully integrated into the guide base 52. In particular, nozzles that allow the purge gas 29 to flow into the waveguide output 14 directly or indirectly are formed in the guide base 52. In particular, it is possible that the guide base 52 acts as a part of the cover 23 of the hollow waveguide. In that case, it is possible in particular to dispense with a separate cover in the region of the waveguide output 14.

In yet further exemplary embodiments, the waveguide purging device may be independent of the illumination light guide 50. For example, the guide base 52 may serve only to mechanically connect the illumination light guide 50 to a cover 23, in which the waveguide purging device is formed, or to a separate waveguide purging device.

By use of the guide base 52, it is possible to attach the illumination light guide 50 to the hollow waveguide 11a in such a way that the guide input 55 is arranged flush with the waveguide output 14. The guide input 55 serves as the entry point for the illumination light 3 that emerges from the waveguide output 14 of the hollow waveguide 11a.

The guide main body 51 has a longitudinal axis L that in particular runs parallel to the direction of propagation of the illumination light 3 and that in particular coincides with the direction of propagation of the illumination light 3.

In that case, the guide input 55 and the guide output 56 are in planes that are orthogonal to the longitudinal axis L and found at the respective ends of the guide main body 51. The guide main body 52 takes the form of a hollow body that surrounds an interior in which the illumination light 3 is guided from the guide input 55 to the guide output 56. The guide input 55 is formed in the guide base 52; the guide output 56 is formed in the guide cover plate 53.

The interior has a cross section that is defined perpendicular to the longitudinal axis L. The cross section has a cross-sectional area and a cross-sectional shape. In this context, the cross-sectional shape should be understood to mean the shape of the contour of the cross section, independently of the circumference and/or the surface area of the cross-sectional area of the interior. In particular, it is possible that different cross-sectional areas the same in terms of surface area have different cross-sectional shapes. Moreover, two cross sections with different cross-sectional areas can have the same cross-sectional shape, for example a round or square cross-sectional shape.

In some implementations, the guide input 55 has a different cross-sectional shape to the guide output 56. At the guide input 55 and at the guide output 56, the interior in each case has the same cross-sectional shape as the guide input 55 and the guide output 56, respectively. The cross-sectional shape of the cross section of the interior changes along the longitudinal axis L between the guide input 55 and guide output 56. The cross-sectional shape changes along the longitudinal axis, in particular continuously. The cross-sectional shape of the interior may in particular change smoothly, i.e. without edges and/or kinks, along the longitudinal axis L. It is also possible that the cross-sectional shape of the interior changes discontinuously.

In the exemplary embodiment shown, the guide input 55 has a circular cross-sectional shape. The guide output 56 has an elliptical cross-sectional shape.

In other exemplary embodiments (not shown in the figures), the guide input 55 and the guide output 56 may also have a polygonal cross-sectional shape, in particular a rectangular cross-sectional shape. For example, a cross-sectional shape of the guide input 55 may be a regular polygon, in particular a square. The cross-sectional shape of the guide output 56 may be a non-regular polygon, in particular a rectangle. Combinations of round cross-sectional shapes with polygonal cross-sectional shapes are also possible.

Upon emergence from the guide output 56, the illumination light 3 in particular has a cross-sectional shape of the beam cross section that corresponds to the cross-sectional shape of the guide output 56.

In the exemplary embodiment shown in FIGS. 5 to 7, the guide output 56 has a larger cross-sectional area than the guide input 55. The interior of the guide main body 52 and the guide main body 52 take a conical form. The cross section of the interior changes in such a way that a cross-sectional area increases, in particular increases monotonically, along the longitudinal axis L, while, at the same time, the initially circular cross-sectional shape of the interior transitions into a final elliptical cross-sectional shape.

In particular, the cross-sectional shape of the guide input 55 has an input side ratio S₁ that is substantially equal to 1. As a result of an input side ratio S₁ that is substantially equal to 1, the illumination light guide 50 can be attached particularly easily to a hollow waveguide 11a. Manufacture is simplified on account of the symmetry in the region of the guide input 55. The purge gas supply is also improved, in particular particularly uniform.

In particular, the input side ratio S₁ may be defined as the ratio of the length to width of the smallest rectangle that forms an envelope for the cross section of the guide input 55, i.e. in particular of the smallest rectangle whose area completely contains the cross section of the guide input 55. For a circular cross-sectional shape, such an enveloping rectangle takes the form of a square, as a result of which an input side ratio S₁ of 1 arises. A diameter of the guide input 55 with a circular cross-sectional shape may in particular be in the range of 10 mm to 20 mm, in particular be of the order of approximately 15 mm.

In this example, the guide output 56 has an output side ratio S₂ that is not equal to 1. For the guide output 56, the output side ratio S₂ is defined analogously to the input side ratio S₁ of the guide input 55. For an elliptical cross-sectional shape, the output side ratio S₂ corresponds to the quotient of the major axis and the minor axis of the ellipse. In particular, the semimajor axis of the ellipse may have a length in the range of 30 mm to 60 mm, in particular of the order of approximately 45 mm. In particular, the semiminor axis of the ellipse may have a length in the range of 20 mm to 40 mm, in particular of the order of approximately 30 mm. In particular, the following may apply to the output side ratio S₂: 1.1<S₂<1.9 and in particular S₂=1.5.

A number of embodiments of the invention have been described. Nevertheless, it will be understood that various modifications can be made without departing from the spirit and scope of the invention. For example, the shapes, geometry, and/or dimensions of various components of the illumination optics unit 1, the illumination system 2, and/or the mask inspection system can be different from those described above.

While some embodiments, examples or aspects described herein include some but not other features included in other embodiments, examples or aspects combinations of features of different embodiments, examples or aspects are meant to be within the scope of the claims, and form different embodiments, as would be understood by those skilled in the art. The embodiments of the present invention that are described in this specification and the optional features and properties respectively mentioned in this regard should also be understood to be disclosed in all combinations with one another. The description of a feature comprised by an embodiment-unless explicitly explained to the contrary-should also not be understood such that the feature is essential or indispensable for the function of the embodiment. Accordingly, other embodiments are within the scope of the following claims.

What is claimed is:

1. An illumination light guide for guiding EUV or DUV illumination light in an illumination optics unit, comprising
a guide main body,
a guide input and
a guide output,
wherein the guide main body forms an interior for guiding the illumination light along a longitudinal axis from the guide input to the guide output and
wherein a cross-sectional shape of the interior defined perpendicular to the longitudinal axis changes along the longitudinal axis.

2. The illumination light guide of claim 1, wherein a cross section of the guide input defined perpendicular to the longitudinal axis has an input side ratio S₁ and a cross section of the guide output defined perpendicular to the longitudinal axis has an output side ratio S₂, with S₁ and S₂ differing from each other.

3. The illumination light guide of claim 2, wherein S₂ is not equal to 1.

4. The illumination light guide of claim 2, wherein S₁ substantially equals 1.

5. The illumination light guide of claim 2, wherein the following applies to S₂: 1.1<S₂<1.9.

6. The illumination light guide of claim 1, wherein the guide main body has a conical shape.

7. The illumination light guide of claim 1, wherein the guide input has a circular cross-sectional shape.

8. The illumination light guide of claim 1, wherein the guide output has an elliptical cross-sectional shape.

9. The illumination light guide of claim 1, wherein the cross-sectional shape of the guide input is a regular polygon.

10. The illumination light guide of claim 1, wherein the cross-sectional shape of the guide output is an irregular polygon.

11. The illumination light guide of claim 1, wherein at least one functional component for influencing optical component parts disposed upstream in the illumination optics unit is at least partially integrated into the illumination light guide in the region of the guide input.

12. The illumination light guide of claim 11, wherein a purging device for purging upstream optical components is at least partially integrated into the illumination light guide.

13. An illumination optics unit having an illumination light guide of claim 1 and a light source.

14. The illumination optics unit of claim 13, comprising an optical hollow waveguide assembly having a hollow waveguide and a waveguide purging device.

15. The illumination optics unit of claim 14, wherein the waveguide purging device is at least partially integrated into the illumination light guide.

16. An inspection apparatus having an illumination optics unit of claim 13.

17. The inspection apparatus of claim 16, comprising an optical hollow waveguide assembly having a hollow waveguide and a waveguide purging device.

18. The inspection apparatus of claim 17, wherein the waveguide purging device is at least partially integrated into the illumination light guide.

19. The illumination optics unit of claim 13, wherein a cross section of the guide input defined perpendicular to the longitudinal axis has an input side ratio S₁ and a cross section of the guide output defined perpendicular to the longitudinal axis has an output side ratio S₂, with S₁ and S₂ differing from each other.

20. The illumination optics unit of claim 13, wherein the guide main body has a conical shape.
